(19) United States
(12) Patent Application Publication
(10) Pub. No.: US 2026/0020137 A1
(43) Pub. Date: Jan. 15, 2026

(54) HEAT DISSIPATION SHEET, CIRCUIT BOARD, AND ELECTRONIC DEVICE

(71) Applicant: Chipbond Technology Corporation, Hsinchu (TW)

(72) Inventors: Dong-Sheng Li, Hsinchu (TW); Yi Ling Hsieh, Hsinchu (TW); Pei-Ying Lee, Hsinchu (TW); San Lee, Hsinchu (TW)

(21) Appl. No.: 19/247,297

(22) Filed: Jun. 24, 2025

(30) Foreign Application Priority Data
Jul. 10, 2024 (TW) 113125777

(51) Int. Cl. H05K 1/02

(52) U.S. Cl. CPC H05K 1/0203; H05K 1/028; H05K 2201/066

(57) ABSTRACT

The present disclosure provides a heat dissipation sheet to be adhered to a circuit board. The heat dissipation sheet includes a first adhesive layer to be adhered to the circuit board, a heat dissipation layer arranged over the first adhesive layer, a protection layer arranged over the heat dissipation layer, and a plurality of heat dissipation holes extending downward from an upper surface of the protection layer, wherein bottoms of the plurality of the heat dissipation holes are not lower than an upper surface of the first adhesive layer or a lower surface of the heat dissipation layer.

### BACKGROUND OF THE INVENTION

### Field of the Invention

The present disclosure relates to a heat dissipation sheet, a circuit board and an electronic device having the heat dissipation sheet.

### Description of the Prior Art

In the prior art, a chip is generally arranged on a printed circuit board, and a flexible circuit board (for example, a tape carrier package (TCP) or chip-on-film (COF)), owing to its bendability, and is frequently used in an electronic device with a small space to carry a chip.

A chip or other electronic elements on a circuit board may generate heat in operation. In order to optimize heat dissipation effects, a heat dissipation sheet is usually adhered to the circuit board and covers the chip or other electronic elements that generate heat.

With respect to the above, for example, reference is made to Patent Document 1 (Taiwan Patent Publication No. 202207383), which specifically discloses, in FIG. 3, a display device including a flexible circuit board in a COF package. A chip serving as a driver integrated circuit (IC) for a display panel, and a heat dissipation sheet adhered to the circuit board and covering the chip are provided on the flexible circuit board (refer to FIG. 2A and FIG. 2B of Patent Document 1 for details). In particular, the heat dissipation sheet is also a flexible heat dissipation sheet that is bendable along with the flexible circuit board, so as to be suitable for an electronic device with a small space. As for other similar heat dissipation sheets, reference may be also made to Patent Document 2 (Taiwan Patent Publication No. 202221868) of the applicant.

### SUMMARY OF THE INVENTION

With extensive research, the applicant discovers that the prior art above faces numerous issues in practice. For example, in Patent Document 1 and Patent Document 2, the surface of the heat dissipation sheet facing downward is adhered to the circuit board or the chip by an adhesive (for example, an adhesive material such as a pressure-sensitive adhesive and a thermosetting resin), and the surface of the heat dissipation sheet facing upward is provided with an insulating protection layer. The insulating protection layer is generally made of insulating materials that mostly pertain to polymer materials such as polyimide (PI), so as to provide the heat dissipation sheet with an insulation effect and sufficient mechanical strength. The heat dissipation sheet is provided with a heat dissipation layer (for example, a metal layer or graphite) therein, and is able to assist with heat dissipation of the circuit board or the chip below. However, compared with the heat dissipation layer, polyimide itself is not considered a good heat conductive material (having a thermal conductivity coefficient of about 0.2 to 2 W/m·k). Thus, heat transferred from the circuit board or the chip to the heat dissipation layer cannot be further quickly transferred to the exterior for natural convection. Therefore, there is still room for improvement in respect of heat dissipation effects of such conventional heat dissipation sheet.

Moreover, it is discovered that, such conventional heat dissipation sheet is not kept leveled when adhered to the circuit board but is often subject to bending, that is, as shown in FIG. 2A and FIG. 2B of Patent Document 1. In addition, the extent of bending of such conventional heat dissipation sheet becomes more severe when adhered to a bendable region of the circuit board, that is, as shown in FIG. 3 of Patent Document 1. In this case, a heat dissipation sheet having a small area is susceptible to peeling off from the circuit board due to stress, and this also accounts for another drawback that needs to be improved.

In view of the above, a novel heat dissipation sheet is provided according to an embodiment of the present disclosure, and more particularly, a flexible and bendable heat dissipation sheet to be adhered to a circuit board, and more particularly, to be adhered to a bendable region of a circuit board. The heat dissipation sheet includes a first adhesive layer to be adhered to the circuit board, a heat dissipation layer arranged over the first adhesive layer, a protection layer arranged over the heat dissipation layer, and a plurality of heat dissipation holes extending downward from an upper surface of the protection layer, wherein bottoms of the plurality of the heat dissipation holes are not lower than an upper surface of the first adhesive layer or a lower surface of the heat dissipation layer on both sides. Preferably, the bottoms of the plurality of heat dissipation holes may be located in the heat dissipation layer, or more preferably, the bottoms of plurality of heat dissipation holes are not lower than an upper surface of the heat dissipation layer.

In addition, a novel heat dissipation sheet is further provided according to another embodiment of the present disclosure, and more particularly, a flexible and bendable heat dissipation sheet to be adhered to a circuit board, and more particularly, to be adhered to a bendable region of a circuit board. The heat dissipation sheet includes a first adhesive layer to be adhered to the circuit board, a heat dissipation layer arranged over the first adhesive layer, a protection layer arranged over the heat dissipation layer, and a plurality of heat dissipation holes extending downward from an upper surface of the protection layer, wherein the heat dissipation sheet has two opposite edges and a distance between the plurality of heat dissipation holes and one of the two edges is less than 25% of a distance between the two edges.

A circuit board is further provided according to an embodiment of the present disclosure. The circuit board includes a substrate and the heat dissipation sheet stated above to be adhered to the substrate. An electronic device is further provided according to an embodiment of the present disclosure. The electronic device includes the circuit board mentioned above and a chip arranged on the circuit board.

### BRIEF DESCRIPTION OF THE DRAWINGS

FIG. 1 is a structural schematic diagram of a heat dissipation sheet according to a first embodiment of the present disclosure;

FIG. 2 to FIG. 10 are structural schematic diagrams of heat dissipation sheets according to other different embodiments of the present disclosure;

FIG. 11 is a top view of a heat dissipation sheet according to an embodiment of the present disclosure; and

FIG. 12 is a schematic diagram of an electronic device according to an embodiment of the present disclosure.

### DETAILED DESCRIPTION OF THE EMBODIMENTS

Embodiments of the present disclosure are described with reference to the accompanying drawings below. To prevent obscuring of content of the present disclosure, conventional elements, related materials and related processing techniques are omitted from the description below. Meanwhile, in order to clearly describe the present disclosure, the various elements in the accompanying drawings are not necessarily drawn to actual scales or relative ratios.

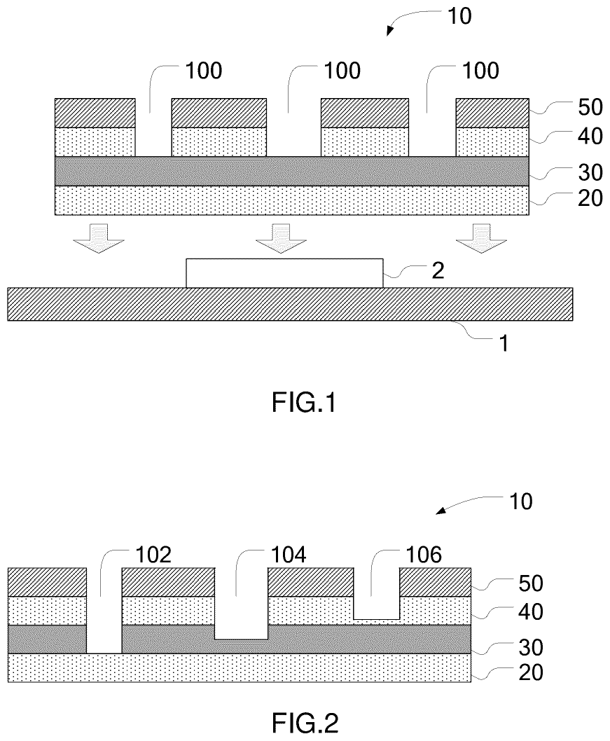

Refer to a side view in FIG. 1 showing a heat dissipation sheet 10 according to a first embodiment of the present disclosure. The heat dissipation sheet 10 is to be adhered onto a circuit board 1 and/or a chip 2. As references, the circuit board 1 and the chip 2 may each be a flexible circuit board (for example, a tape carrier package (TCP) or a chip-on-film (COF)) in the prior art, and the heat dissipation sheet 10 may be adhered to a bendable region (not shown) of the circuit board 1.

As shown in the drawing, the heat dissipation sheet 10 includes a first adhesive layer 20, a heat dissipation layer 30, a second adhesive layer 40 and a protection layer 50.

The first adhesive layer 20 in one aspect is to come into contact downward with and be adhered to the circuit board 1 and/or the chip 2, and in another aspect is to come into contact upward with and be adhered to the heat dissipation layer 30. The first adhesive layer 20 may be made of a material selected from adhesive materials such as a double-sided tape, a pressure-sensitive adhesive and a thermosetting resin, and has a thickness usually not less than 1 μm. For example, the first adhesive layer 20 is a 8805 heat conductive tape manufactured by 3M™.

The heat dissipation layer 30 may be made of a material selected from heat conductive/heat dissipating materials such as metal or graphite. In some embodiments, the heat dissipation layer 30 may be a copper foil or an aluminum foil.

The second adhesive layer 40 in one aspect is to come into contact downward with and be adhered to the heat dissipation layer 30, and in another aspect is to come into contact upward with and be adhered to the protection layer 50. The second adhesive layer 40 may be made of a material the same as or similar to that of the first adhesive layer 20.

The protection layer 50 may be made of a material selected from insulating materials such as organic polymer materials, or is referred to as an insulating layer. In some embodiments, the protection layer 50 may be a polyimide (PI) film.

Further, as shown in FIG. 1, the heat dissipation sheet 10 is characterized by having multiple heat dissipation holes 100. In an embodiment, the aperture of the heat dissipation holes 100 is at least 0.5 mm, or is, for example, 1 mm or 1.2 mm, and the spacing among the heat dissipation holes 100 is at least 1 mm. The heat dissipation holes 100 penetrate downward and extend from an upper surface of the protection layer 50 to an upper surface of the heat dissipation layer 30, and expose the heat dissipation layer 30. Thus, heat gathered by the heat dissipation layer 30 can be more transferred to the exterior via a path (that is, the heat dissipation holes 100) other than the second adhesive layer 40 and the protection layer 50. The method for forming the heat dissipation holes 100 may be implemented by, for example, mechanical drilling or laser drilling. It should be noted that, for illustration purposes, FIG. 1 depicts only three heat dissipation holes 100. However, the actual number of the heat dissipation holes 100 may be more, and is not specifically defined by the present disclosure.

It should also be noted that, in the embodiment in FIG. 1, the heat dissipation holes 100 penetrate the protection layer 50 and the second adhesive layer 40, and bottoms thereof are located at an upper surface of the heat dissipation layer 30 to expose the heat dissipation layer 30. In addition, as for the form of the heat dissipation holes of the present disclosure, reference may be made to the embodiment in FIG. 2, wherein heat dissipation holes 102, 104 and 106 having three different depths are depicted.

Compared with the heat dissipation holes 100 in FIG. 1, the heat dissipation hole 102 in FIG. 2 is deeper, penetrates through the heat dissipation layer 30 and exposes the first adhesive layer 20. The position of a bottom of the heat dissipation hole 102 is located at an upper surface of the first adhesive layer 20. The heat dissipation hole 104 in FIG. 2 is deeper than the heat dissipation holes 100 in FIG. 1, but does not penetrate through the heat dissipation layer 30 as the heat dissipation hole 102 does. As shown in the drawing, the position of a bottom of the heat dissipation hole 104 is located in the heat dissipation layer 30 but does not yet expose the first adhesive layer 20. Compared with the prior art, both of the approaches above allow heat gathered by the heat dissipation layer 30 to be more quickly transferred to the exterior via a path (that is, the heat dissipation hole 102 or the heat dissipation hole 104) other than the second adhesive layer 40 and the protection layer 50.

The heat dissipation hole 106 in FIG. 2 is shallower than the heat dissipation holes 100 in FIG. 1, and the position of a bottom thereof on one hand does not reach the heat dissipation layer 30 and does not expose the heat dissipation layer 30, and on the other hand is lower than a lower surface of the protection layer 50 and is located in the second adhesive layer 40. A heat dissipation path for the heat dissipation layer 30 provided by the heat dissipation hole 106, although passing through a small part of the second adhesive layer 40, is nonetheless able to improve heat dissipation as it avoids passing through the protection layer 50 having poor thermal conductivity. However, to ensure heat dissipation effects, some embodiments minimize the second adhesive layer 40 on the heat dissipation path. In some embodiments, the depth by which the heat dissipation hole 106 enters the second adhesive layer 40 may be more than ⅓ of the thickness of the entire second adhesive layer 40; that is, the position of the bottom of the heat dissipation hole 106 is lower than the position at ⅔ of the thickness of the entire second adhesive layer 40.

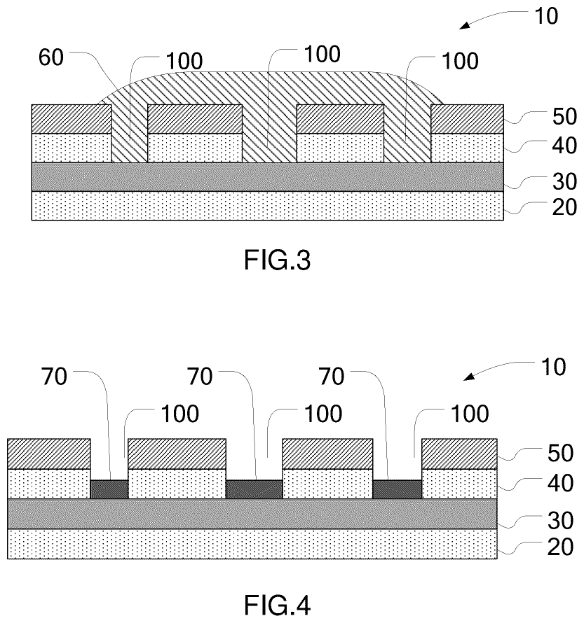

Next, refer to FIG. 3 showing the heat dissipation sheet 10 according to another embodiment of the present disclosure. Compared with the embodiment in FIG. 1, the heat dissipation sheet 10 of this embodiment primarily differs in that, the multiple heat dissipation holes 100 in the heat dissipation sheet 10 are filled with a heat dissipation adhesive 60 having a thermal conductivity coefficient less than 100 W/m·k and a viscosity less than 25,000 Pa·s, thereby enhancing the heat dissipation effects of the heat dissipation holes 100 as a heat dissipation path. The heat dissipation adhesive 60 may be a thermosetting encapsulation adhesive consisting of, for example, epoxy resin/silicone and oxidized metal powder (or a mixture of other metals and non-metals).

Next, refer to FIG. 4 showing the heat dissipation sheet 10 according to another embodiment of the present disclosure. Compared with the embodiments in FIG. 1 and FIG. 3, the heat dissipation sheet 10 of this embodiment primarily differs in that, the multiple heat dissipation holes 100 in the heat dissipation sheet 10 are further filled with a heat conductive metal 70, thereby enhancing the heat dissipation effects of the heat dissipation holes 100 as a heat dissipation path. The heat conductive metal 70 may be, for example, copper paste, silver paste or tin paste, and can be filled into the heat dissipation holes 100 by means of screen printing, electroplating or sputtering.

Next, refer to FIG. 5 showing the heat dissipation sheet 10 according to another embodiment of the present disclosure. Compared with the embodiment in FIG. 1, the heat dissipation sheet 10 of this embodiment primarily differs in that, the heat dissipation sheet 10 further includes a thermal diffusion layer 80 arranged between the heat dissipation layer 30 and the second adhesive layer 40. In this embodiment, the heat dissipation holes 100 penetrate and extend downward from the upper surface of the protection layer 50 and all the way to an upper surface of the thermal diffusion layer 80 to expose the thermal diffusion layer 80. The function of the thermal diffusion layer 80 is to serve as a thermal interface material to more quickly diffuse heat accumulated in the heat dissipation layer 30 to the exterior. In some embodiments, a thermal conductivity coefficient in the horizontal direction (the X and Y axes) of the thermal diffusion layer 80 is greater than a thermal conductivity coefficient in the vertical direction (the Z axis) of the thermal diffusion layer 80 by at least 50%. The thermal diffusion layer 80 may be, for example, graphite having a thickness of about 50 μm.

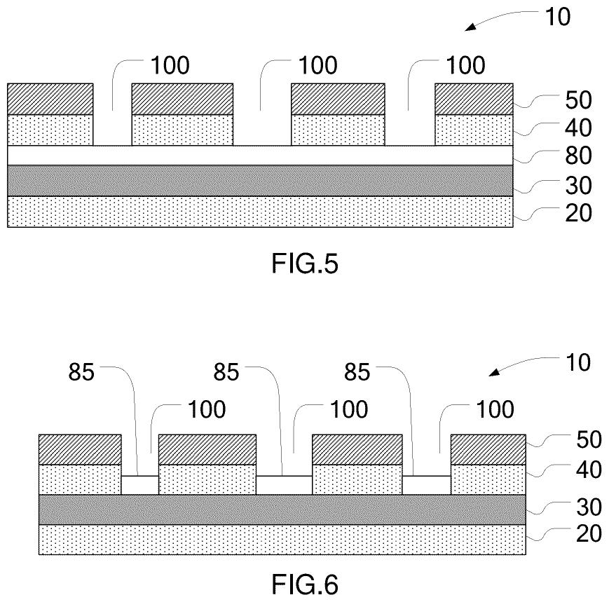

Refer to FIG. 6 showing the heat dissipation sheet 10 according to another embodiment of the present disclosure. Compared with the embodiments in FIG. 1 and FIG. 5, the heat dissipation sheet 10 of this embodiment primarily differs in that, a thermal diffusion layer 85 is arranged at the bottoms of the heat dissipation holes 100. The thermal diffusion layer 85 may be made of a material with reference to the thermal diffusion layer 80 in FIG. 5.

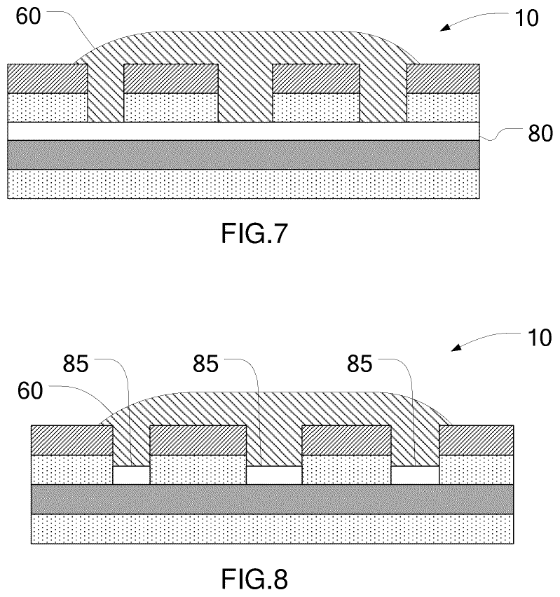

It is to be further noted that, the embodiment having the thermal diffusion layer 80 in FIG. 5 may be added with the heat dissipation adhesive 60 in FIG. 3, that is, as the embodiment shown in FIG. 7. Similarly, the embodiment having the thermal diffusion layer 85 in FIG. 6 may be added with the heat dissipation adhesive 60 in FIG. 3, that is, as the embodiment shown in FIG. 8.

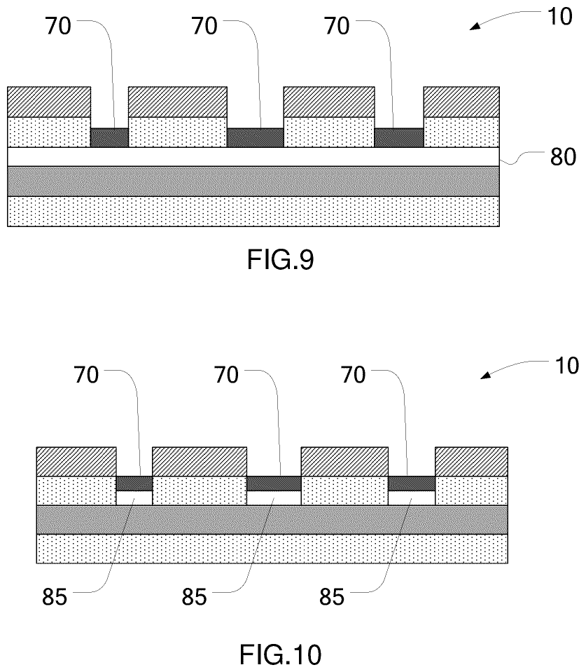

Meanwhile, the embodiment having the thermal diffusion layer 80 in FIG. 5 may be added with the heat conductive metal 70 in FIG. 4, that is, as the embodiment shown in FIG. 9. Similarly, the embodiment having the thermal diffusion layer 85 in FIG. 6 may be added with the heat conductive metal 70 in FIG. 4, that is, as the embodiment shown in FIG. 10.

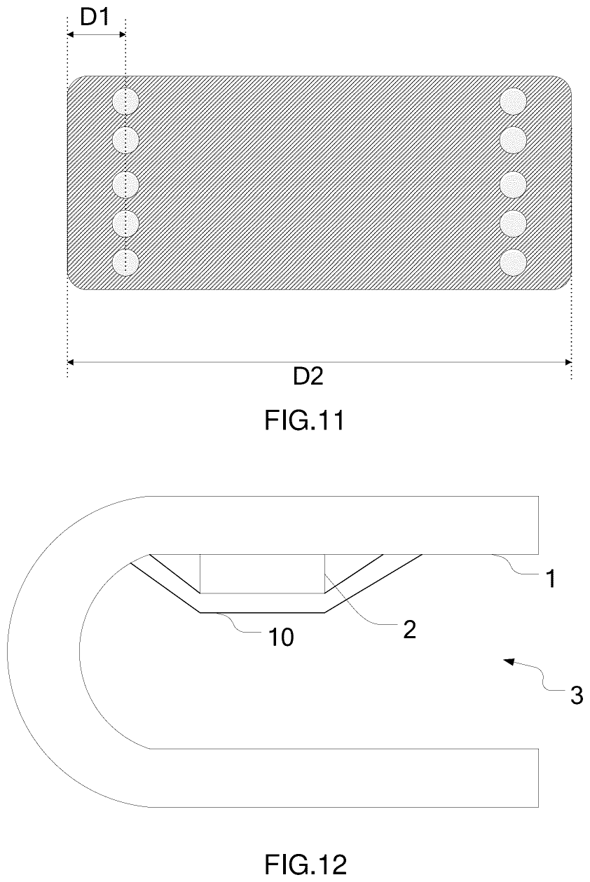

Different from FIG. 1 to FIG. 10 showing side views, FIG. 11 shows a top view of the heat dissipation sheet 10 according to another embodiment. As shown in FIG. 11, the heat dissipation sheet 10 has a substantially rectangular shape, and a specific size that can be adjusted according to actual conditions. Bending mainly occurs on long sides of a rectangle, and thus both sides (that is, positions of short sides) of the long sides are subject to significant action of stress.

As shown in FIG. 11, the heat dissipation sheet 10 is arranged with the multiple heat dissipation holes 100 in FIG. 1 (or the heat dissipation hole 102, 104 or 106 in FIG. 2), and the multiple heat dissipation holes 100 are arranged in linear arrays along edges of the short sides of the heat dissipation sheet 10. The heat dissipation holes 100 provide an effect of alleviating the stress because part of the structural material is removed. In some embodiments, as a distance D1 between the array formed by the heat dissipation holes 100 and the edge of one short side of the heat dissipation sheet 10 gets shorter, the stress can be more effectively alleviated. In some embodiments, the distance D1 is less than 6 mm, and is, for example, 6 mm, 3 mm or 1 mm. In another embodiment, the distance D1 between the heat dissipation holes 100 and the edge of one short side of the heat dissipation sheet 10 is less than 25% of a distance D2 between the edge of the short side to the edge of the opposite short side, for example, the distance D1 may be 10% or 25% of the distance D2. It should also be noted that, for illustration purposes, FIG. 11 depicts only two arrays on the left and right each having 5*1 heat dissipation holes 100. However, in other embodiments, a greater number of heat dissipation holes 100 (or the heat dissipation hole 102, 104 or 106 in FIG. 2) arranged at other positions may be provided.

FIG. 12 shows an electronic device 3 according to an embodiment of the present disclosure. The electronic device 3 includes a flexible circuit board 1, and a chip 2 and the heat dissipation sheet 10 arranged on the flexible circuit board 1. Refer to the description in conjunction with FIG. 1 to FIG. 11 above for details of the heat dissipation sheet 10. The electronic device 3 can be, for example, a flat display, a wearable device, a cell phone, a tablet computer, a laptop computer, an in-vehicle panel, an industrial control panel, and the chip 2 can be, for example, a chip for driving image display. As shown in FIG. 12, due to the small space within the electronic device 3, the circuit board 1 is inevitably bent for usage therein. Associated details are well known by a person of ordinary skill in the art and are thus omitted herein. Moreover, in an embodiment which is not shown, the electronic device 3 is not necessarily a product for immediate use of an end user, and can be a semi-finished product in need of subsequent processing as long as the chip 2 is already arranged on the circuit board 1. It should be further noted that, in other embodiments that are not shown, the heat dissipation sheet 10 may also be adhered to a back surface (that is, the surface not arranged with the chip 2) of the circuit board 1, and such is not specifically defined by the present disclosure.

The description above provides embodiments of the present disclosure, and is not to be construed as limitations to the scope of the claims of the present disclosure. All equivalent changes or modifications completed without departing from the spirit disclosed by the present disclosure are encompassed within the scope of the appended claims.

What is claimed is:

1. A heat dissipation sheet to be adhered to a circuit board, the heat dissipation sheet comprising:
a first adhesive layer, to be adhered to the circuit board;
a heat dissipation layer, arranged over the first adhesive layer;
a protection layer, arranged over the heat dissipation layer; and
a plurality of heat dissipation holes, extending downward from an upper surface of the protection layer, wherein bottoms of the plurality of heat dissipation holes are not lower than an upper surface of the first adhesive layer.

2. The heat dissipation sheet according to claim 1, wherein the bottoms of the plurality of heat dissipation holes are located in the heat dissipation layer.

3. The heat dissipation sheet according to claim 1, wherein the bottoms of the plurality of heat dissipation holes are not lower than an upper surface of the heat dissipation layer.

4. The heat dissipation sheet according to claim 3, further comprising a thermal diffusion layer arranged between the heat dissipation layer and the protection layer, wherein the bottoms of the plurality of heat dissipation holes are not lower than an upper surface of the thermal diffusion layer, and a thermal conductivity coefficient in a horizontal direction of the thermal diffusion layer is greater than a thermal conductivity coefficient in a vertical direction of the thermal diffusion layer by at least 50%.

5. The heat dissipation sheet according to claim 1, further comprising a thermal diffusion layer located at the bottoms of the plurality of heat dissipation holes, wherein a thermal conductivity coefficient in a horizontal direction of the thermal diffusion layer is greater than a thermal conductivity coefficient in a vertical direction of the thermal diffusion layer by at least 50%.

6. The heat dissipation sheet according to claim 1, further comprising a second adhesive layer arranged between the heat dissipation layer and the protection layer, wherein the bottoms of the plurality of heat dissipation holes are lower than a lower surface of the protection layer.

7. The heat dissipation sheet according to claim 6, wherein the bottoms of the plurality of heat dissipation holes are lower than a position at ⅔ of a thickness of the second adhesive layer.

8. The heat dissipation sheet according to claim 1, wherein the plurality of heat dissipation holes are further filled with a heat dissipation adhesive.

9. The heat dissipation sheet according to claim 1, wherein the plurality of heat dissipation holes are further filled with a heat conductive metal.

10. The heat dissipation sheet according to claim 1, wherein an aperture of the plurality of heat dissipation holes is at least 0.5 mm.

11. The heat dissipation sheet according to claim 1, wherein a spacing among the plurality of heat dissipation holes is at least 1 mm.

12. The heat dissipation sheet according to claim 1, wherein a distance between the plurality of heat dissipation holes and an edge of the heat dissipation sheet is not greater than 6 mm.

13. The heat dissipation sheet according to claim 1, wherein the heat dissipation sheet has two opposite edges, and a distance between the plurality of heat dissipation holes and one of the two edges is not greater than 25% of a distance between the two edges.

14. A circuit board, comprising:
a substrate, having a circuit layer; and
the heat dissipation sheet according to claim 1, the heat dissipation sheet adhered to the substrate.

15. An electronic device, comprising:
the circuit board according to claim 14; and
a chip, arranged on the circuit board.
